(19) United States
(12) Patent Application Publication
(10) Pub. No.: US 2005/0115602 A1
(43) Pub. Date: Jun. 2, 2005

(54) Photo-electric conversion cell and array, and photo-electric generation system

(75) Inventors: Hirofumi Senta, Yokaichi-shi (JP); Takeshi Kyoda, Yokaichi-shi (JP); Kenichi Okada, Yokaichi-shi (JP); Hisao Arimune, Yokaichi-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 10/892,592

(22) Filed: Jul. 15, 2004

(30) Foreign Application Priority Data
Nov. 28, 2003 (JP) JP2003-398792
Jan. 28, 2004 (JP) JP2004-020583

(51) Int. Cl. H01L 31/113; H01L 31/062; H01L 31/00

(52) U.S. Cl. 136/250; 136/256

(57) ABSTRACT

A photo-electric conversion array is formed by connecting photo-electric conversion cells in series. Each photo-electric conversion cell includes: a substrate, at least one main surface of which is made of a conductor layer; plural crystalline semiconductor particles provided on the conductor surface of the substrate; an insulation layer filled in clearances among the crystalline semiconductor particles; a transparent electric conducting layer provided above the plural crystalline semiconductor particles; a collector electrode, formed on the transparent electric conducting layer, to collect electricity from the transparent electric conducting layer. The substrate is provided with a substrate electrode portion at one end portion, through which the conductor surface of the substrate is exposed, and a connection electrode is formed by extending the collector electrode, so that the connection electrode in a given photo-electric conversion cell is connected to the substrate electrode portion in another photo-electric conversion cell. It is thus possible to provide a photo-electric conversion array capable of maintaining the reliability as to the adhesion strength, with a good outward appearance as well as excellent reliability and power generation efficiency.

### BACKGROUND OF THE INVENTION

1. Field of the Invention

The present invention relates to a photo-electric conversion cell for use in photovoltaic generation or the like, comprising a substrate, at least one main surface of which is made of a conductor layer, crystalline semiconductor particles to perform photo-electric transfer, a transparent electric conducting layer to serve as the other electrode, and a collector electrode to collect a current from the transparent electric conducting layer. The invention also relates to a photo-electric conversion array comprising serially-connected photo-electric conversion cells and a photo-electric generation system.

2. Description of the Related Art

In a case where photo-electric conversion cells are connected in series, the collector electrode of a given photo-electric conversion cell needs to be connected to the substrate electrode of an adjacent photo-electric conversion cell. For the electrode used for this connection (hereinafter, referred to as the connection electrode), materials are selected adequately from those having a low resistance, such as a metal bar and a wire.

Sets of the serially-connected photo-electric conversion cells are connected in parallel to achieve the required output. These sets are sealed with a filling material made of ethylene vinyl acetate (EVA), serving as a protection material, to form a photo-electric transfer module.

The connection electrode is conventionally thought to connect the collector electrode of a given photo-electric conversion cell to another photo-electric conversion cell adjacent to this photo-electric conversion cell on a surface of the substrate where no crystalline semiconductor particles are placed, that is, the lower surface of the substrate.

According to the structure to connect the photo-electric conversion cells as described above, however, the number of steps is increased by having to turn over a photo-electric conversion cell in the process. Also, turning over a photo-electric conversion cell reduces a connection strength during the process, which causes disconnection or the like. Defective items are thus produced frequently, and a concern as to the reliability is being raised. In addition, the length of the connection electrode is extended, which not only makes the connection electrode difficult to handle, but also increases the material costs of the connection electrode.

The invention was devised in view of the foregoing problems, and has advantages that it provides a photo-electric conversion cell, a photo-electric conversion array, and a photo-electric generation system, all of which are excellent in workability and productivity because they can be readily and easily fabricated, and are capable of shortening the connection electrode; moreover, all of which are able to achieve satisfactory reliability and power generation efficiency.

### BRIEF SUMMARY OF THE INVENTION

The advantages of the invention can be achieved by a photo-electric conversion cell, including: a substrate, at least one main surface of which is made of a conductor layer; plural crystalline semiconductor particles provided on the conductor surface of the substrate; an insulation layer filled in clearances among the crystalline semiconductor particles; a transparent electric conducting layer provided above the plural crystalline semiconductor particles; and a collector electrode, formed on the transparent electric conducting layer, to collect electricity from the transparent electric conducting layer, wherein the substrate is provided with a substrate electrode portion at one end portion, through which the conductor surface of the substrate is exposed.

According to this photo-electric conversion cell, the substrate is provided with the substrate electrode portion through which the conductor surface is exposed. Hence, by connecting a connection electrode between the substrate electrode portion and the collector electrode, it is possible to connect the photo-electric conversion cells on the light-incident surfaces. This eliminates the need to turn over the photo-electric conversion cell, which makes the connection work easier and hence the workability more excellent. Moreover, the connection strength will not be deteriorated.

It is preferable that the insulation layer is also formed on a side surface of the substrate at an end portion where the substrate electrode portion is not provided. The insulation layer provided to the side surface of the substrate can prevent the leakage of a current caused when the connection electrode comes in contact with the substrate while the photo-electric conversion cells are connected to one another. This eliminates the need for a conventionally essential member, such as an insulation tape.

A photo-electric conversion array of the invention is formed by connecting photo-electric conversion cells in series. Each photo-electric conversion cell includes: a substrate, at least one main surface of which is made of a conductor layer; plural crystalline semiconductor particles provided on the conductor surface of the substrate; an insulation layer filled in clearances among the crystalline semiconductor particles; a transparent electric conducting layer provided above the plural crystalline semiconductor particles; and a collector electrode, formed on the transparent electric conducting layer, to collect electricity from the transparent electric conducting layer. The substrate is provided with a substrate electrode portion at one end portion, through which the conductor surface of the substrate is exposed. Also, a given photo-electric conversion cell is connected to another photo-electric conversion cell via a connection electrode that electrically connects the collector electrode in a given photo-electric conversion cell to the substrate electrode portion in another photo-electric conversion cell.

According to the photo-electric conversion array of the invention, in a case where plural photo-electric conversion cells are connected in series, the collector electrode in a given photo-electric conversion cell is connected to the substrate electrode portion in an adjacent photo-electric conversion cell via the connection electrode. This eliminates the need to turn over the photo-electric conversion cell, and the reliability as to the connection strength can be thus maintained. In addition, it is possible to provide a photo-electric conversion array having a good outward appearance with excellent reliability and power generation efficiency.

The electrical connection of the connection electrode and the substrate electrode portion can be achieved by means of ultrasonic welding. The photo-electric conversion cells can be thus connected in series more easily and promptly. It is thus possible to provide a photo-electric conversion array with extremely satisfactory connection workability and connection reliability.

The connection electrode may be an electrode extended from the collector electrode. In this case, the collector electrode is allowed to serve also as the connection electrode, and the connection electrode can be provided in the step of forming the collector electrode. The fabrication of the photo-electric conversion array can be thus simplified.

It is preferable that the connection electrode and the collector electrode, an extension of which forms the connection electrode, are composed of a metal bar coated with a non-lead solder layer on a surface thereof. A sufficient bonding strength can be maintained by using the metal bar coated with the non-lead solder layer on the surface. Also, the mechanical property and the electric characteristic can be satisfactory with the use of a metal bar having a lower resistance.

It is preferable that the metal bar is chiefly made of one of copper and aluminum, and the non-lead solder layer is chiefly made of tin. The non-lead solder layer can prevent, as much as possible, the oxidation on the surface of copper or aluminum used as the chief component. It is thus possible to provide a photo-electric conversion array having a good outward appearance with a stable characteristic. Also, an environmentally benign photo-electric conversion array can be provided because non-lead solder is used.

It is desirable that a bent portion is formed somewhere in the middle of the connection electrode. The bent portion exerts the buffer function, which minimizes, for example, the occurrence of breaking in the connection electrode caused upon a shift of the photo-electric conversion cell in position. It is thus possible to provide a highly reliable photo-electric conversion array.

It may be possible to adopt a configuration, in which the collector electrode is composed of a finger electrode and a bus bar electrode both formed on the transparent electric conducting layer; the connection electrode is an electrode extended from the bus bar electrode; and the finger electrode and the bus bar electrode are electrically connected to each other via an anisotropic electric-conducting adhesion agent disposed in between. Because the bus bar electrode and the finger electrode are adhered to each other by pressing via the anisotropic electric-conducting adhesion agent containing metal particles, the metal particles are expected to provide the anchor effect (the effect by which the bus bar electrode and the finger electrode are adhered to each other by pressing with an applied pressure for the metal particles in the resin disposed in between to be incorporated into the bus bar electrode and the finger electrode, thereby causing the both electrodes to be fixed with each other). The term “anisotropic” referred to herein is defined as conductive in a pressurized direction due to contact among metal particles, and insulating in a non-pressurized direction.

The connection electrode may be an electrode bonded onto the collector electrode. According to this configuration, the connection electrode is formed separately from the collector electrode, and the connection electrode and the collector electrode are attached to the outside. The collector electrode can therefore adopt the conventional structure, which makes it possible to achieve a cost-efficient photo-electric conversion array.

It is preferable that the connection electrode is composed of a metal bar coated with a non-lead solder layer on a surface thereof, and it is preferable that the metal bar is chiefly made of one of copper and aluminum, while the non-lead solder layer is chiefly made of tin. Further, by forming a bent portion somewhere in the middle of the connection electrode, an impact generated at or after the connection can be absorbed.

It is preferable that the collector electrode occupies a region that accounts for 10% to 40%, both inclusive, of an area of air spaces among the semiconductor particles. When this condition is satisfied, a current can be collected efficiently without reducing the efficiency of the photovoltaic generation caused by shadows, and the photo-electric conversion array becomes quite effective for practical use.

The collector electrode may be formed by subjecting electric conducting paste, made of heat-cured resin that contains an electric conducting material, to heat treatment. According to this forming method, the collector electrode can be formed easily, and can improve the economical merits markedly. The industrial value of the photo-electric conversion array is therefore quite high. In particular, because heat-cured resin is used, the collector electrode can be formed at low temperatures, which enables ITO, a suitable electric conducting material, to be used as the transparent electric conducting layer beneath the collector electrode.

The collector electrode has a function of collecting a current flowing through the transparent electric conducting layer, and in order to fully exert such a function, it is preferable that a gradient of concentration is set in such a manner that a concentration of the electric conducting material contained in the collector electrode becomes higher on a side closer to the transparent electric conducting layer.

In addition, a photo-electric generation system of the invention is fabricated with the use of the photo-electric conversion array described above.

### BRIEF DESCRIPTION OF THE DRAWINGS

FIG. 1 is a cross section showing one embodiment of a photo-electric conversion cell of the invention, using particle-shaped crystalline semiconductors as photo-electric transducers;

FIG. 2 is a cross section of the photo-electric conversion cell, showing a connected state of a bus bar electrode 9 and a finger electrode 7;

FIG. 3 is a plan view of the photo-electric conversion cell;

FIG. 4 is a cross section of the photo-electric conversion cell used to explain one example of a forming method of substrate electrode portions 1a;

FIG. 5 is a cross section of the photo-electric conversion cell used to explain another example of the forming method of the substrate electrode portions 1a;

FIG. 6 is a plan view showing a photo-electric conversion array formed by connecting the photo-electric conversion cells in series;

FIG. 7 is a cross section showing a connected state of the photo-electric conversion cells;

FIG. 8 is a cross section used to explain a forming method of a bent portion E in a connection electrode 9a;

FIG. 9 is a plan view of the photo-electric conversion cell used to explain a covering ratio of collector electrodes;

FIG. 10 is a cross section showing another embodiment of the photo-electric conversion cell of the invention;

FIG. 11 is a cross section showing a state where a connection electrode 12 is attached to the photo-electric conversion cell; and

FIG. 12 is a cross section showing a state where the connection electrode 9a is connected to a metal substrate 1 in an adjacent photo-electric conversion cell on a surface opposite to a light-incident surface.

### DETAILED DESCRIPTION OF THE INVENTION

Embodiments of the invention will now be described in detail with reference to the accompanying drawings.

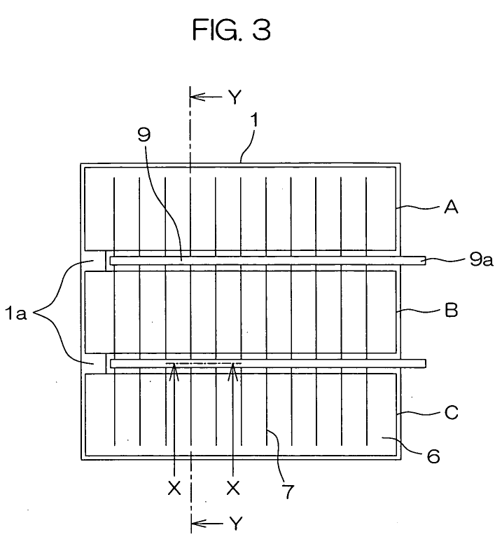

FIG. 1 is across section along Y-Y line of FIG. 3, showing one embodiment of a photo-electric conversion cell using particle-shaped crystalline semiconductors as photo-electric transducers.

The photo-electric conversion cell includes a substrate 1, plural crystalline semiconductor particles 3 provided on the conductor surface of the substrate 1, an insulation layer 4 filled in clearances among crystalline semiconductor particles 3, a semiconductor layer 5 and a transparent electric conducting layer 6 both provided above the crystalline semiconductor particles 3.

One main surface of the substrate 1 is formed of an aluminum conductor layer. The crystalline semiconductor particles 3 are silicon particle-shaped crystalline semiconductors showing one conduction type (for example, the p-type) and provided on the conductor surface of the substrate 1. The semiconductor layer 5 is a semiconductor layer of the opposite conduction type (for example, the n-type) provided above the crystalline semiconductor particles 3.

Also, numeral 2 denotes an alloy portion of aluminum of the substrate 1 and silicon of each crystalline semiconductor particle 3. Numeral 7 denotes a finger electrode provided on the transparent electrode layer 6. Numeral 9 denotes a bus bar electrode attached to the finger electrode 7 at almost right angles. Numeral 8 denotes an anisotropic electric-conducting adhesive agent to connect the finger electrode 7 and the bus bar electrode 9.

The bus bar electrode 9 comprises a metal bar 10 made of, for example, a copper foil, and a non-lead solder layer 11 that coats the metal bar 10.

The finger electrode 7 and the bus bar electrode 9 together form a collector electrode.

The substrate 1 may be an insulator provided with an aluminum conductor on the surface. Examples of the insulator include ceramics, such as alumina. One or more than one kind of element selected from silicon, magnesium, manganese, chromium, titanium, nickel, zinc, silver, and copper may be added to the aluminum conductor layer. By adding such an element to the aluminum conductor layer, it is possible to prevent over-melting of the crystalline semiconductor particles 3 when bonded to the aluminum conductor layer. A film thickness of the aluminum conductor layer is preferably 20 μm or greater. A film thickness less than 20 μm is too thin for the aluminum conductor layer to be bonded to the crystalline semiconductor particles 3, and the satisfactory bonding cannot be achieved.

Alternatively, the entire substrate 1 may be made of metal, such as aluminum.

Metal on the surface layer of the substrate 1, or metal forming the entire substrate 1 may be iron, stainless, nickel alloy, etc. in addition to aluminum.

On one main surface of the substrate 1 are provided a number of crystalline semiconductor particles 3 of a first conduction type. The crystalline semiconductor particles 3 are provided on the substrate 1, and the substrate 1 and the crystalline semiconductor particles 3 are welded through the treatment, for example, at or above the eutectic temperature of aluminum and silicon. The crystalline semiconductor particles 3 are made of Si doped with a slight quantity of elements used as a p-type impurity, such as B, Al, and Ga, or elements used as an n-type impurity, such as P and As.

The particle size of the crystalline semiconductor particles 3 is preferably 0.2 to 0.8 mm. When the particle size exceeds 0.8 mm, a quantity of used silicon is almost the same as that in the conventional crystalline plate-type photo-electric conversion cell, and the merits using the crystalline semiconductor particles are eliminated. Conversely, when the particle size is less than 0.2 mm, a light transmission factor is increased and so is a loss of light energy, which reduces the transfer efficiency. In addition, there arises another problem that the assembly onto the substrate 1 becomes difficult. When the relation with a quantity of used silicon is concerned, the particle size of the crystalline semiconductor particles 3 is more preferably 0.2 to 0.6 mm.

The insulation layer 4 is made of an insulation material to separate a positive electrode and a negative electrode. For example, it may be a glass composite combined with a filler made of low-temperature firing glass material, or an insulator chiefly made of silicone resin or polyimide resin.

The insulation material is formed in clearances among the crystalline semiconductor particles 3 on the substrate 1. To be more concrete, according to this forming method, the insulation material is applied above the crystalline semiconductor particles 3, followed by heating at or below 577° C., the eutectic temperature of aluminum and silicon. The insulation material is then cured and eventually fills the clearances. When the heating temperature exceeds 577° C., the alloy portion 2 of aluminum and silicon starts to melt, which makes the bonding between the substrate 1 and the crystalline semiconductor particles 3 unstable, and in some cases, the crystalline semiconductor particles 3 come apart from the substrate 1, thereby making it impossible to take a power generation current. After the insulation material 4 fills the clearances, the surfaces of the crystalline semiconductor particles 3 are rinsed.

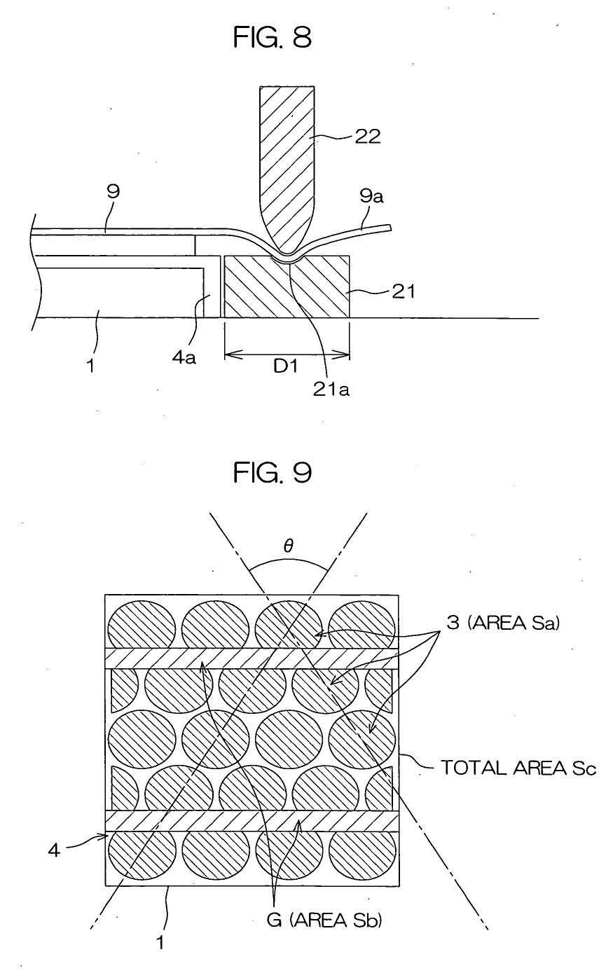

In the invention, in order to prevent the leakage of a current when connecting the photo-electric conversion cells, as will be described with reference to FIG. 7 below, the insulation layer 4 covers the substrate 1 continuously to the edge, and preferably, to the side surface below the edge of the substrate 1.

The semiconductor layer 5, showing the opposite conduction type, is formed above the crystalline semiconductor particles 3 along the surface in the shape of a convex curve. By forming the semiconductor layer 5 above the crystalline semiconductor particles 3 along the surface in the shape of a convex curve, a larger area can be secured for the p-n junction, which makes it possible to collect the carriers, generated inside the crystalline semiconductor particles 3, in an efficient manner.

The semiconductor layer 5 is formed by introducing a slight quantity of a phosphorous-based compound in the vapor phase, such as phosphine (PH₃), used as an n-type impurity, or a boron-based compound in the vapor phase, used as a p-type impurity, into a silane compound in the vapor phase. The semiconductor layer 5 can be a film made of either a crystalline or amorphous material, or a mixture of crystalline and amorphous materials. The electric conductivity of the semiconductor layer 5 is set in such a manner that the concentration of a slight quantity of elements in the layer is, for example, in the order of 1×10¹⁶ to 1×10²¹ atoms/cm³.

The semiconductor layer 5 can be omitted in a case where elements of the opposite conduction type, to be more specific, a slight quantity of elements, such as P and As showing the n-type or elements, such as B, Al, and Ga showing the p-type, is used for the shell of the crystalline semiconductor particles 3. In this case, the transparent electric conducting layer 6 may be formed directly above the crystalline semiconductor particles 3.

On the semiconductor layer 5 is formed the transparent electric conducting layer 6. The transparent electric conducting layer 6 is an oxide-based electric conducting film made of one or more than one type of oxide selected from SnO₂, In₂O₃, ITO, ZnO, TiO₂, etc. The transparent electric conducting layer 6 is formed by the film deposition method, such as sputtering, spray CVD and vapor phase deposition, or by means of application firing. If the thickness is adequately selected, the transparent electric conducting layer 6 is expected to serve effectively also as an antireflection coating.

The finger electrodes 7 are electrodes provided on the semiconductor layer 5 or the transparent electric conducting layer 6 in parallel at regular intervals in lowering the resistance of the semiconductor layer 5 and the transparent electric conducting layer 6.

As is shown in FIG. 1, the bus bar electrode 9 is provided on the transparent electric conducting layer 6 at the flat portion where the crystalline semiconductor particles 3 are not welded to the substrate 1. The bus bar electrode 9 comprises a metal bar 10 and a non-lead solder layer 11 coating the metal bar 10. As will be described below, the extended portion of the bus bar electrode 9 forms a connection electrode 9a used to connect the photo-electric conversion cells.

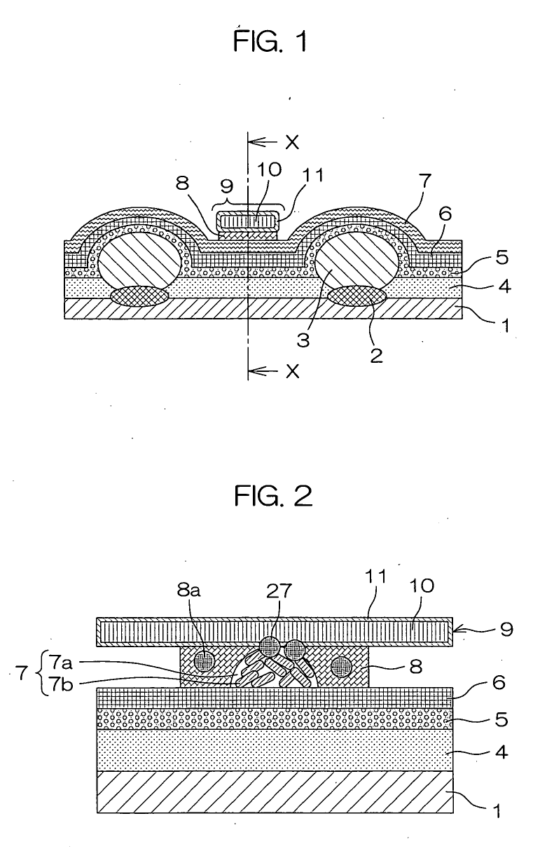

FIG. 2 is a cross section showing a connected state of the bus bar electrode 9 and the finger electrode 7. The cross section is taken along the alternate long and short dash line X-X of FIG. 1.

As is shown in the cross section, on the substrate 1 are formed the insulation layer 4, the semiconductor layer 5, and the transparent electric conducting layer 6 from bottom to top in this order. On the transparent electric conducting layer 6 is formed the finger electrode 7 in a direction perpendicular to the sheet surface. Also, the bus bar electrode 9 is bonded to the transparent electric conducting layer 6 and the finger electrode 7 with the anisotropic electric-conducting adhesive agent 8 at the right angles with the finger electrode 7.

As an electrode material for the finger electrodes 7, low-temperature-cured electric conducting paste, containing conductor powder 7b having a low resistance, such as gold, silver, and copper, and a binder 7a made of heat-cured resin containing a small quantity of solvent, is used. A temperature needed to cure the heat-cured resin is preferably 400° C. or below. When a temperature needed to cure the heat-cured resin exceeds 400° C., the semiconductor layer 5 undergoes degeneration, which makes it impossible to achieve a sufficient transfer efficiency.

The heat-cured resin referred to herein means resin based on silicone, epoxy, urethane, phenol, etc. Epoxy-based resin has a low resistance as well as excellent weather resistance in comparison with the other resin materials, and is optimal in terms of the adhesion to the transparent conducting layer 6 and the workability. For example, it is preferable to form the finger electrodes 7 using 80 to 95 wt % of Ag and 5 to 20 wt % of epoxy resin.

The finger electrodes 7 are made of an electric conducting material of the heat-cured type as described above, and therefore they can be formed at low temperatures. This allows the use of ITO, which is a suitable material for the transparent electric conducting layer 6. The finger electrodes 7 can be formed by means of screen printing, a dispenser, etc.

As has been described, the bus bar electrodes 9 comprise the metal bar 10 and the non-lead solder layer 11 coating the metal bar 10. It is particularly preferable that the metal bar 10 is chiefly made of copper or aluminum. It is preferable that the non-lead solder layer 11 is chiefly made of tin.

Because the non-lead solder layer 11 has an effect of preventing the oxidation and erosion on the surface of the metal bar 10, it is possible to provide a photo-electric conversion cell having a good outward appearance as well as a stable electric characteristic. In addition, light reflect on the metal bar 10 is expected to provide an effect of increasing the generation efficiency in some degree.

A material forming the non-lead solder layer 11 excludes Pb because of environmental concerns, and therefore is alloy solder made of at least Sn as a chief component and one or more than one element selected from Cu, Ni, and Ag. Examples include (1) alloy made of 78.4 wt % of Sn, 2.0 wt % of Ag, 9.8 wt % of Bi, and 9.8 wt % of In; (2) alloy made of 0.2 to 6.0 wt % of Zn, 1 to 6 wt % of Ag, and Sn for the rest as a chief component; (3) alloy made of 3.1 to 7 wt % of Ag, 6 to 30 wt % of Bi, and Sn for the rest as a chief component; (4) alloy made of 0.05 to 2.0 wt % of Cu, 0.001 to 2.0 wt % of Ni, and Sn for the rest as a chief component; or (5) alloy made of 0.1 to 2.0 wt % of Cu, 0.002 to 1.0 wt % of Ni, and Sn for the rest as a chief component. Alternatively, alloy chiefly made of Sn and containing Cu, Ni, Ag, Bi, and In can be used as well.

The bus bar electrode 9 and the finger electrode 7 are electrically connected to each other as a pressure is applied to the both via the anisotropic electric-conducting adhesion agent 8 disposed in between.

The anisotropic electric-conducting adhesion agent 8 is made of resin containing electric conducting particles 8a, such as Ni, which are harder than the bus bar electrode material and the finger electrode material. The bus bar electrode 9 and the finger electrode 7 are adhered to each other by pressing via the anisotropic electric-conducting adhesion agent 8. The metal particles 8a are expected to provide the anchor effect (the effect by which metal particles coming out from the resin through adhesion by pressing are incorporated into the bus bar electrode and the finger electrode, thereby causing the both electrodes to be fixed with each other).

As has been described, the bus bar electrodes 9 comprise the metal bar 10 coated with the non-lead solder layer 11 on the surface, and are adhered to the finger electrodes 7 by pressing via the anisotropic electric conducting adhesion agent 8. It is thus possible to ensure a sufficient adhesion strength in comparison with the conventional case where electric conducting paste is used for the bus bar electrode. Further, an excellent current characteristic can be attained due to the use of the metal bar 10 having a lower resistance. Moreover, it is possible to provide an environmentally benign photo-electric conversion cell having a good outward appearance.

FIG. 3 is a plan view of the photo-electric conversion cell. Capitals A, B, and C represent regions of the photo-electric conversion cell where the crystalline semiconductor particles 3 are placed. On across the entire surface of the photo-electric conversion cell is formed the transparent electric conducting layer 6, except for portions indicated by alpha-numeral 1a. On the transparent electric conducting layer 6 are formed the finger electrodes 7 at almost regular intervals in a direction perpendicular to the sheet surface. In the portions except for the regions A, B, and C, that is, a portion between the region A and the region B and an portion between the region B and the region C, are formed the bus bar electrodes 9 in a direction orthogonal to the direction along which the finger electrodes 7 are formed.

In this invention, as is shown in FIG. 3, the bus bar electrodes 9 come out from the right end face of the photo-electric conversion cell. These coming-out portions 9a in this photo-electric conversion cell function as connection electrodes that are electrically connected to the substrate electrode in an adjacent photo-electric conversion cell.

The bus bar electrodes 9 do not reach the left end face of the photo-electric conversion cell, and leave portions indicated by alpha-numeral 1a of FIG. 3. In these portions, because none of the insulation layer 4, the semiconductor layer 5, and the transparent electric conducting layer 6 is formed, the substrate 1 is exposed. These exposed portions are referred to as the substrate electrode portions 1a.

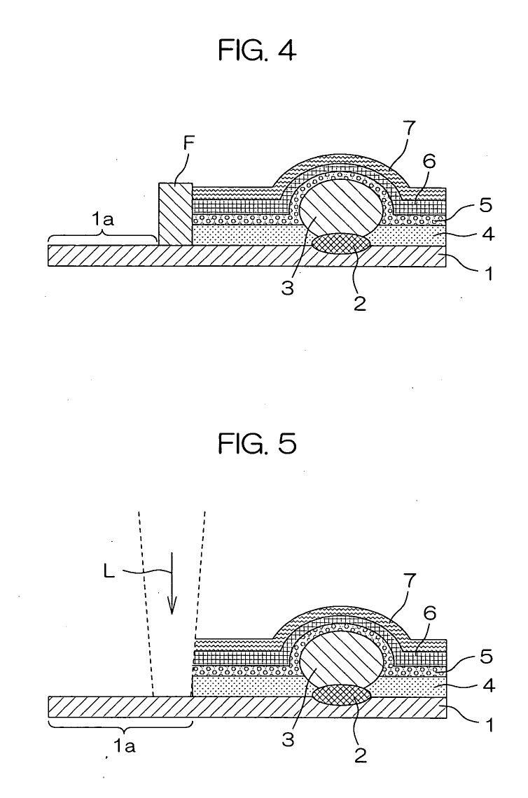

FIG. 4 and FIG. 5 are cross sections of the photo-electric conversion cell used to explain the forming method of the substrate electrode portions 1a.

As is shown in FIG. 4, a bank F made of heat-cured resin or UV-cured resin is formed by a dispenser on the substrate 1 in the periphery of portions where the substrate electrodes portions 1a are to be formed. The insulation layer 4 is applied on the inner side of the substrate 1 under these conditions. The bank F is then removed, and the semiconductor layer 5 and the transparent electric conducting layer 6 are formed while the portions to be made into the substrate electrodes portions 1a are covered with a metal mask. Alternatively, the substrate electrode portions 1a may be covered with easy-to-remove resin instead of the metal mask, and the resin is removed after films of the semiconductor layer 5 and the transparent electric conducting layer 6 are deposited.

Besides the method of FIG. 4, all the insulation layer 4, the semiconductor layer 5, and the transparent electric conducting layer 6 may be formed, so that the substrate electrode portions 1a are formed by cutting out the deposited films until the substrate 1 is exposed. As such a removing method, the deposited films may be removed by a laser beam L as is shown in FIG. 5.

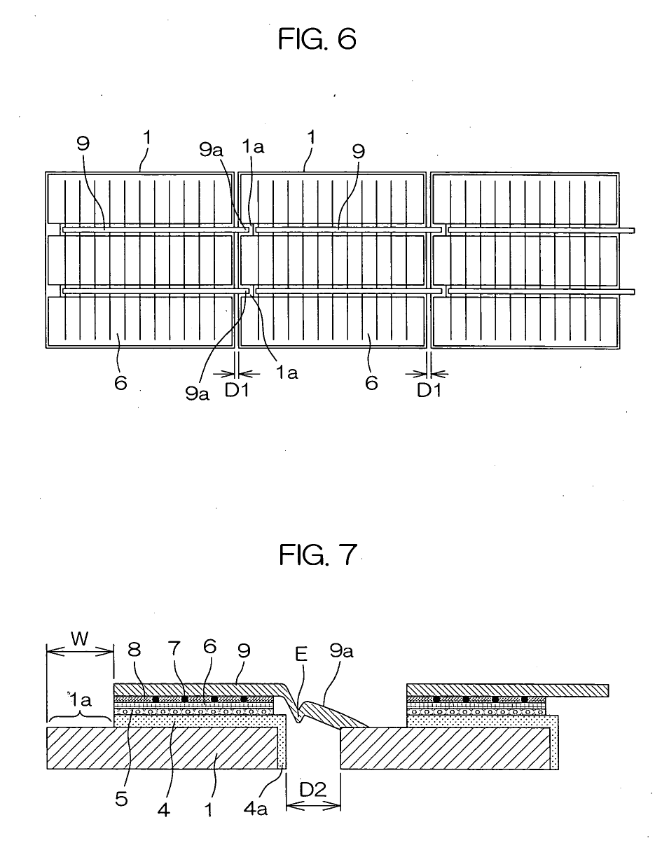

FIG. 6 is a plan view showing a photo-electric conversion array comprising plural serially-connected photo-electric conversion cells. The connection electrodes 9a coming out from a given photo-electric conversion cell are connected to the substrate electrode portions 1a in an adjacent photo-electric conversion cell.

Both the connection electrodes 9a and the substrate electrode portions 1a are provided to the light-incident surface side of the photo-electric conversion cell, and this configuration enables the photo-electric conversion cells to be connected in series on the light-incident surface side. A distance D1 between adjacent photo-electric conversion cells is preferably 0.5 to 1 mm.

The connecting method of the connection electrodes 9a can be achieved by means of bonding with the use of solder, ultrasonic welding, rivets, etc., and any can be adopted. It should be noted that when the substrate 1 is made of aluminum, the bonding with the use of solder fails to attain a sufficient bonding strength, and the connection by means of ultrasonic welding or rivets is therefore preferable. In particular, the ultrasonic welding makes the connection work easier and is excellent in workability and productivity. It should be noted that in the case of the connection by means of rivets, of all the material available for the rivets, including Cu, Al, Fe, etc., Cu or Al is preferable in terms of the electric conductivity and the cost, etc.

For the connection electrodes 9a, it is preferable to form a bent portion E in each connection electrode 9a somewhere in the middle as is shown in FIG. 7. The bent portion E functions as a buffer portion when the connection electrode 9a is connected to the corresponding substrate electrode portion 1a in an adjacent photo-electric conversion cell. Because the bent portion E servers as the buffer portion, it is possible to minimize, for example, the occurrence of the braking in the connection electrode 9a due to a force applied upon a shift of the photo-electric conversion cell in position. A highly reliable photo-electric conversion cell can be thus provided.

FIG. 8 is a view used to explain the forming method of the bent portion E. A rectangular parallelepiped piece 21, which has a width D1 and is allowed to abut on one side of the substrate 1 in the photo-electric conversion cell, is prepared. A groove 21a parallel to one surface of the rectangular parallelepiped piece 21 is formed in advance in the rectangular parallelepiped piece 21. The cross section of the groove 21a is shaped like a letter U or a letter V. A compression edge 22 having a blade that can be fitted to the groove 21a is provided movably in a vertical direction. The bent portion E is formed in the connection electrode 9a by causing the connection electrode 9a to abut on the rectangular parallelepiped piece 21 and then by pressing the compression edge 22 from above.

Further, according to the photo-electric conversion cell of the invention, as is shown in FIG. 7, an extended portion of the insulation layer 4 is formed on the side surface of the substrate 1 at the end where the connection electrodes 9a are formed. The extended portion of the insulation layer 4 is indicated by alpha-numeral 4a. By forming the extended portion 4a of the insulation layer 4 on the side surface of the photo-electric conversion cell, it is possible to prevent the leakage of a current caused when the connection electrodes 9a come in contact with the substrate 1 while the photo-electric conversion cells are connected to one another.

FIG. 9 is a partial plan view of the photo-electric conversion cell used to explain a covering ratio of the finger electrodes 7 and the bus bar electrodes 9. The finger electrodes 7 and the bus bar electrodes 9 are collectively referred to as the collector electrodes G.

In a region of the photo-electric conversion cell shown in FIG. 9, let Sb be an area occupied by the collector electrodes G, Sa be an area occupied by the crystalline semiconductor particles 3 (except for the portions of the collector electrodes G), and Sc be a total area of the region of the photo-electric conversion cell. Then, a covering ratio K of the collector electrodes G is defined as:
K=100Sb/(Sc−Sa)[%]

When the area of the collector electrodes G becomes too small, the ability to collect a current from the transparent conductor is deteriorated markedly, which makes it impossible to increase the transfer efficiency of the overall device. It is therefore preferable to set the covering ratio K to 10% or higher. Conversely, when the area of the collector electrodes G becomes too large, crystalline semiconductor particles 3 are covered more than necessary, which also reduces the transfer efficiency of the overall device. It is therefore preferable to set the covering ratio K to 40% or lower. In short, a preferable range of the covering ratio K is from 10% to 40%, both inclusive.

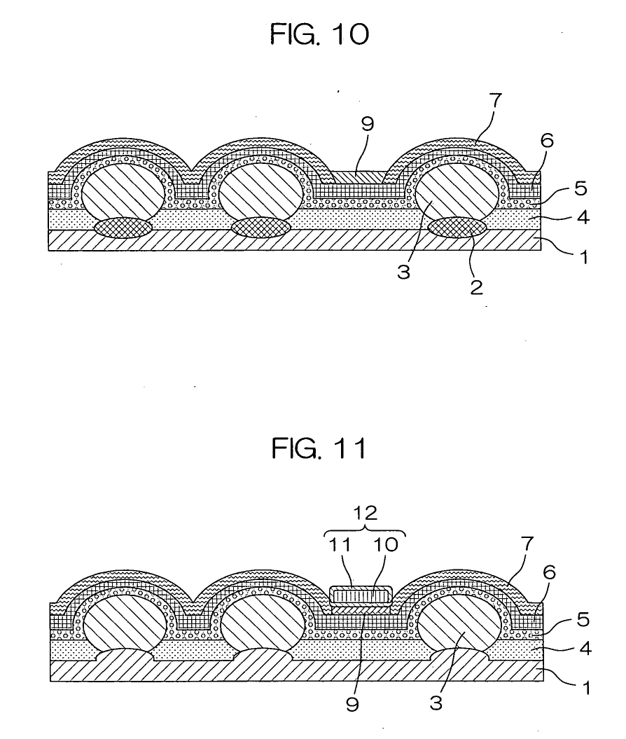

FIG. 10 and FIG. 11 are cross sections showing another embodiment of the invention.

A photo-electric conversion cell of this embodiment includes, as with the photo-electric conversion cell of FIG. 1, a substrate 1, plural crystalline semiconductor particles 3 provided on the conductor surface of the substrate 1, an insulation layer 4 filled in clearances among the crystalline semiconductor particles 3, and a semiconductor layer 5 and a transparent electric conducting layer 6 both provided above the plural crystalline semiconductor particles 3.

This photo-electric conversion cell is also the same as the aforementioned photo-electric conversion cell in that finger electrodes 7 are provided on the transparent electric conducting layer 6, and that exposed portions 1a are provided to the substrate 1.

A difference from FIG. 1 is that bus bar electrodes 9 formed on the transparent electric conducting layer 6 are not made of a metal bar coated with a non-lead solder layer; they are instead made of low-temperature-cured electric conducting paste containing conductor powder and a binder made of heat-cured resin containing a slight quantity of solvent, like the finger electrodes 7.

Also, as is shown in FIG. 11, a connection electrode 12, comprising a metal bar 10 coated with a non-lead solder layer 11, is attached on the bus bar electrode 9 with the use of solder.

As has been described, epoxy resin is preferable as the heat-cured resin in terms of adhesion to the transparent electric conducting layer 6. However, when the connection electrodes 12 are bonded with the use of solder after the bus bar electrodes 9 are formed, epoxy resin is firmly fixed onto the surface of the electric conducting powder on the surfaces of the bus bar electrodes 9. Under these conditions, epoxy resin may not be able to decompose depending on the temperature and the flux at the time of the bonding with the use of solder, and may hinder the bonding of the solder to the connection electrodes 12 and the bus bar electrodes 9.

To address this inconvenience, it is preferable to add 30 to 70 mass % of phenol resin, so that the bonding of the connection electrodes 12 can be achieved without hindering the bonding to epoxy resin with the use of solder. By adding 30 to 70 mass % of phenol resin to epoxy resin in this manner, it is possible to improve the bus bar electrodes 9 as to the bonding to the connection electrodes 12 while maintaining the adhesion to the transparent electric conducting layer 6.

It is preferable that a gradient of concentration is given to the concentration of the conductor powder contained in the finger electrodes 7 and the bus bar electrodes 9 in such a manner that the concentration of the conductor powder becomes higher on the side closer to the transparent electric conducting layer 6. This is because the current collecting ability is determined by the ability to receive and collect electrons from the transparent electric conducting layer 6. Due to the presence of metal at a high density in the finger electrodes 7 and the bus bar electrodes 9 on the side closer to the transparent electric conducting layer 6, the efficiency of electron conduction is improved and so is the current collecting ability of a solar cell. The power generation efficiency of the photo-electric conversion cell can be thus increased.

On the other hand, the connection electrodes 12 provided on the bus bar electrodes 9 comprise the metal bar 10 and the non-lead solder layer 11 coating the metal bar 10. As with the case shown in FIG. 3, the connection electrodes 12 are made to have a length long enough to come out from one end face of the substrate 1 in the photo-electric conversion cell.

The connection electrodes 12 are bonded onto the bus bar electrodes 9 with the use of solder. The solder not only bonds the former to the latter, but also provides an effect of preventing corrosion on the surface of the metal bar 10. A material forming the solder includes alloy solder selected at least from Sn, Cu, Ni, Ag, and Bi. In a case where the bus bar electrode 9 are formed from electric conducting paste made of silver powder, solder containing Ag is preferred in preventing silver-biting into the solder. In a case where the bus bar electrodes 9 are formed from electric conducting paste made of copper powder or copper powder coated with silver on the surface, inexpensive solder excluding Ag is sufficient. Also, after the bus bar electrodes 9 are formed, the solder may be formed on the bus bar electrodes 9 before the connection electrodes 12 are bonded.

As with the case shown in FIG. 7, a bent portion E, functioning as a buffer portion when the connection electrodes 12 are connected to the substrate electrode portions 1a of an adjacent photo-electric conversion cell, may be provided to each connection electrode 12 in a portion coming out from one end face of the substrate 1 in the photo-electric conversion cell.

Plural photo-electric conversion cells fabricated in the manner as described above are prepared, and the connection electrodes 12 of a given photo-electric conversion cell are connected to the exposed portions 1a of the substrate 1 in another photo-electric conversion cell. As with the case described with reference to FIG. 6, ultrasonic welding or the like is preferable as the connection method.

A photo-electric generator system is manufactured by using the above said photo-electric conversion cell and photo-electric conversion array as electric power generators. Generated electric power can be supplied to a load. The photo-electric conversion cell and array can be connected in series, in parallel or in combination of series and parallel so as to transfer electric power directly to the load.

Further, the generated DC power of the photo-electric generator system can be directed to convert the DC power into AC power by means of power conversion device such as an inverter. The generated AC power can be supplied to AC loads such as commercial power lines or various electric devices.

The photo-electric generator system may be disposed on a roof or a wall of a sunny building for generation of efficient photo-electric power.

### EXAMPLES

Examples of the invention reduced to practice will now be described.

A number of crystalline semiconductor particles 3 of a first conduction type were arrayed on the substrate 1 and then heated at 460 to 660° C. for 1 to 20 min. to weld the crystalline semiconductor particles 3 and the substrate 1. An alloy portion 2, chiefly made of aluminum and silicon, was thus formed on the welded portion.

When the heating temperature is below 460° C., the alloy forming reaction does not take place between aluminum and silicon, which makes the welding difficult. Conversely, when the heating temperature exceeds 660° C., the temperature is at or above the melting point of aluminum. Aluminum thus starts to melt or undergo deformation, and is no longer able to function as the substrate.

In a case where the crystalline semiconductor particles 3 are arrayed on the substrate 1, it is possible to perform heat-welding by interposing resin or the like between the substrate 1 and the crystalline semiconductor particles 3 in fixing the crystalline semiconductor particles 3.

Subsequently, the insulation layer 4 was filled in clearances among the crystalline semiconductor particles 3, and fired to be fixed. Further, a semiconductor layer 5 and a transparent electric conducting layer 6 of a second conduction type were formed.

Finger electrodes 7 were then formed on the transparent electric conducting layer 6 in spaces among the crystalline semiconductor particles 3. The finger electrodes 7 were formed by (1) forming a protection film on the transparent electric conducting layer 6 in portions where no finger electrodes 7 were to be formed through masking or the like; (2) printing electric conducting paste or spraying the same with a dispenser; and (3) removing unwanted portions, followed by drying and heat-curing. It should be noted that the forming method is not limited to the method described above, and the vacuum thin-film technique, such as sputtering, vapor phase deposition, and ion plating, can be used as well.

### Example 1-1

A substrate 1 was formed by forming aluminum alloy portions on the both surfaces of an aluminum alloy substrate or SUS 430 through cold rolling via a Ni foil. On the substrate 1 were randomly provided p-type silicon particles 3 while securing intervals from the bus bar attaching positions. Silicon particles 3 were bonded to the aluminum alloy by heating in atmosphere at or above 577° C., which is the eutectic temperature of aluminum and silicon. On top of this, an insulator, chiefly made of polyimide resin, was applied to continuously cover the side surface portion of the substrate 1 while end portions 1a were masked, followed by heating in atmosphere. The insulation layer 4 was thus formed. Subsequently, the top surfaces of the p-type silicon particles 3 were rinsed with a diluted aqueous solution of hydrofluoric acid (HF:pure water=1:100) for cleaning. A semiconductor layer 5, mixed crystals of n-type crystalline silicon and amorphous silicon, was formed above the silicon particles 3 and the insulation layer 4 by masking the substrate electrode portions 1a alone. Further, an ITO film, serving as a transparent electric conducting layer 6, was formed in a thickness of 80 nm by masking the substrate electrode portions 1a alone.

Finger electrodes 7, made of electric conducting paste containing silver powder, were formed at regular intervals on the transparent electric conducting layer 6 in the photo-electric conversion cell fabricated in the manner as described above, and subjected to heat treatment. A copper foil 10 coated with solder made of tin and copper was then attached to the attachment clearances of bus bar electrodes 9 with an electric-conducting adhesive agent 8 without covering the substrate electrode portions 1a as is shown in FIG. 3.

Subsequently, as is shown in FIG. 6, three photo-electric conversion cells were aligned at intervals of 1 mm with the use of jigs 21 (see FIG. 8), and set so that the light-incident surfaces faced upward. In this instance, the connection electrodes 9a of the bus bar electrodes 9 were brought upon the substrate electrode portions 1a. By the setting with the use of the jigs 21, the copper foil between the cells was partially shaped like a letter V or a letter U, that is, in the form of a bent portion. The connection electrodes 9a of the bus bar electrodes 9 were then connected to the substrate electrode portions 1a of a photo-electric conversion cell to be connected, on the light-incident surface side by means of ultrasonic welding.

The ultrasonic welding conditions were: the frequency was 20 kHz, the pressure was 40 PSI (2.8 kgf/cm²), the welding time was 1 sec., and the energy was 2000 joules. A group of serially-connected cells is referred to as Example 1-1.

### Example 1-2

The group of serially-connected cells of Example 1-1 was made into a module by the lamination processing in a vacuum laminating apparatus in the structure: glass substrate/EVA/cell/EVA/PET lamination sheet (back sheet), followed by crosslinking for 30 min. in an oven heated to 150° C. The crosslinking was performed to polymerize molecules of EVA. This module is referred to as Example 1-2. The output terminal was pulled to the back surface before the lamination processing, and pulled out through a take-off made in EVA and the back sheet.

### Example 1-3

The cell connection electrodes were formed from an electric-conducting adhesive agent. The electric-conducting adhesive agent, which was based on resin containing silver or other kinds of electric conducting powder, was adhered by heating and pressing at about 200° C. The rest of the fabrication was the same as that in Example 1-2.

### Example 1-4

A copper foil coated with solder containing tin and copper was used as the cell connection electrodes. The rest of the fabrication was the same as that in Example 1-2.

### Comparative Example 1-1

A substrate was formed by forming aluminum alloy portions on the both surfaces of an aluminum alloy substrate or SUS 430 through cold rolling via a Ni foil. On the substrate were randomly provided p-type silicon particles 3 while securing intervals from the attaching positions of bus bar electrodes 9. Silicon particles 3 were bonded to the aluminum alloy by heating in atmosphere at or above 577° C., which is the eutectic temperature of aluminum and silicon. On top of this, an insulator, chiefly made of polyimide resin, was applied to be formed in the vicinity of the end portion of the substrate, followed by heating in atmosphere. An insulation layer 4 was thus formed. Subsequently, the top surfaces of the p-type silicon particles 3 were rinsed with a diluted aqueous solution of hydrofluoric acid (HF:pure water=1:100) for cleaning. A semiconductor layer 5, mixed crystals of n-type crystalline silicon and amorphous silicon, was formed above the silicon particles 3 and the insulation layer 4. Further, an ITO film, serving as a transparent electric conducting layer 6, was formed in a thickness of 80 nm.

Finger electrodes 7, made of electric conducting paste containing silver powder, were formed at regular intervals on the transparent electric conducting layer 6 in the photo-electric conversion cell fabricated in the manner as described above, and then fired. The bus bar electrodes 9, comprising a copper foil coated with solder made of tin and copper, were then attached to the attaching clearances of the bus bar electrodes 9 with an electric-conducting adhesive agent at the same positions as those in Example 1-1.

Subsequently, six cells were set to jigs (not shown) aligned at intervals of 1 mm, so that the light-incident surfaces faced upward and the protruding connection electrodes 9a were positioned beneath an adjacent cell. The connection electrodes 9a were then connected to the metal substrate on the surface opposite to the light-incident surface by means of ultrasonic welding.

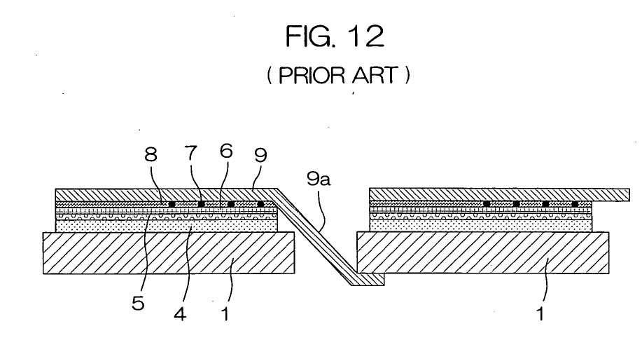

FIG. 12 is a cross section showing the connection electrode 9a connected to the surface opposite to the light-incident surface of the metal substrate in the adjacent photo-electric conversion cell. These serially-connected cells are referred to as Comparative Example 1-1.

### Comparative Example 1-2

The serially-connected cells of Comparative Example 1-1 were subjected to the lamination processing in a vacuum laminating apparatus in the structure: glass substrate/EVA/cell/EVA/back sheet (PET lamination sheet), followed by crosslinking for 30 min. in an oven heated to 150° C. As with Example 1-2, the output terminal was pulled out in advance.

To being with, the both ends of the serial cells of Example 1-1 and the serial cells of Comparative Example 1-1 were fixed, and then a vibration test was conducted. The conditions were: the vibration frequency was 5 to 55 Hz horizontally and 5 to 55 Hz vertically; the sweep time was 120 sec. horizontally and 120 sec. vertically; the acceleration degree of vibrations was 0.75 G horizontally and 1.25 G vertically; the test time was 15 min. for both the X- and Y-directions and 30 min. for the Z-direction. No peeling-off of the copper foil was observed before and after the test in the group of serial cells of Example 1-1. The photo-electric transfer characteristic did not vary before and after the test, either. On the contrary, breaking of the copper foil was observed in several points after the test in Comparative Example 1-1. The reason of this is thought that the copper foil was connected from the top of one substrate to the bottom of the other substrate. In regard to the electric characteristic before and after the test, the curve factor FF induced by the resistance was naturally deteriorated.

Then, the photo-electric transfer characteristic was measured in each of the modules comprising six serially-connected cells of Example 1-2, Example 1-3, Example 1-4, and Comparative Example 1-2, and the data before and after the modularization was compared. The data before after the modularization varied little with the modules of Example 1-2, Example 1-3, and Example 1-4, whereas leakage occurred in Comparative Example 1-2. The reason for this is because the copper foil was connected from the top of one substrate to the bottom of the other substrate as is shown in FIG. 12 and no insulation layer covered the side surface of the substrate, the copper foil was not electrically isolated from the substrate and came in contact with the substrate.

Because the cells were connected on the light-incident surfaces in Example 1-2, Example 1-3, and Example 1-4, a distance between adjacent cells can be shortened as much as possible provided that the insulation of the substrate is ensured. However, because leakage occurs in Comparative Example 1-2 when the cell-to-cell distance is shortened, the adjacent cells can be brought in close proximity only to some extent. In other words, the photo-electric conversion cells of the invention can shorten a cell-to-cell distance in comparison with the conventional cells. It is thus understood that, given with the same module size, the power generation regions in the cells can be increased, which in turn makes it possible to increase the output.

### Example 2-1

A substrate was formed by forming Al alloy portions on the both surfaces of an Al alloy substrate or SUS 430 through cold rolling via a Ni foil. On the substrate were randomly provided p-type Si particles at portions other than the attaching clearances of bus bar electrodes 9. Si particles were then bonded to the Al alloy by heating in atmosphere at or above 577° C., which is the eutectic temperature of Al and Si. On top of this, an insulator, chiefly made of silicone resin, was applied to continuously cover the side surface portion of the substrate 1 while substrate electrode portions 1a and end portions shown in FIG. 3 were masked, followed by heating in atmosphere. An insulation layer 4 was thus formed in clearances among crystalline semiconductor particles 3 comprising Si balls. Subsequently, the top surfaces of the crystalline silicon particles 3 were rinsed with a diluted aqueous solution of hydrofluoric acid (HF:pure water=1:100) for cleaning. A semiconductor layer 5, mixed crystals of n-type crystalline silicon and amorphous silicon, was formed above the crystalline silicon particles 3 and the insulation layer 4 by masking the substrate electrode portions 1a alone. Further, an ITO film, serving as a transparent electric conducting layer 6, was formed in a thickness of 80 nm by masking the substrate electrode portions 1a alone.

Finger electrodes 7, made of epoxy resin, a kind of heat-cure resin, containing silver powder (Ag: 90 wt %, epoxy resin: 10 wt %), were formed at regular intervals on the transparent electric conducting layer 6 in the photo-electric conversion cell fabricated in the manner as described above, and subjected to heat treatment. An isotropic electric-conducting adhesion agent was applied, in a thickness of 50 μm, on a copper foil coated with a non-lead solder layer made of Sn (99 wt %) and Cu (1 wt %), by means of a dispenser. The anisotropic electric-conducting adhesion agent used herein was the one based on epoxy resin and containing 20 wt % of Ni particles having a particle size of 2 μm as the electric conducting particles. The photo-electric conversion cell was then placed on a hot plate heated to 200° C. and heated for 5 min. (because the substrate has a large heat capacity and the temperature does not drop when a copper foil is pressed). Then, as is shown in FIG. 3, the copper foil, on which the anisotropic electric-conducting adhesion agent was applied, was mounted to stride the finger electrodes 7 on the flat portion where no p-type Si particles had been welded to the substrate. At the same time, the copper foil was attached to a jig heated at 220° C. which is in the length as long as the copper foil, and was held for 10 sec. at a pressure of 3.9×10⁵ Pa. The adhesion strength of the copper foil at this instance was 7.8×10⁴ Pa. By observing the cross section taken along the alternate long and short dash line X-X of FIG. 3, it is revealed that, as is shown in FIG. 2, the nickel particles 8a, serving as the electric conducting particles in the resin forming the anisotropic electric-conducting adhesive agent 8, play a role of the anchor. Alpha-numeral 7a of FIG. 2 denotes epoxy resin, a kind of heat-cured resin, forming the finger electrodes 7, and alpha-numeral 7b denotes electric conducting powder, made of silver powder, contained in the epoxy resin.

### Example 2-2

The copper foil was coated with alloy solder made of Sn (98.0 wt %) and Ag (2.0 wt %), and the rest of the fabrication was the same as that in Example 2-1. The adhesion strength in this instance was 8.3×10⁴ Pa.

### Example 2-3

The copper foil was coated with alloy solder made of Sn (99.5 wt %) and Ni (0.5 wt %), and the rest of the fabrication was the same as that in Example 2-1. The adhesion strength in this instance was 7.6×10⁴ Pa.

### Example 2-4

The copper foil was coated with alloy solder made of Sn (99.4 wt %), Cu (0.5 wt %), and Ni (0.1 wt %), and the rest of the fabrication was the same as that in Example 2-1. The adhesion strength in this instance was 8.0×10⁴ Pa.

### Example 2-5

The copper foil was coated with alloy solder made of Sn (96.5 wt %), Cu (3 wt %), and Ag (0.5 wt %), and the rest of the fabrication was the same as that in Example 2-1. The adhesion strength in this instance was 8.1×10⁴ Pa.

### Example 2-6

The copper foil was coated with alloy solder made of Sn (98.5 wt %), Ag (1.0 wt %), and Ni (0.5 wt %), and the rest of the fabrication was the same as that in Example 2-1. The adhesion strength in this instance was 8.0×10⁴ Pa.

### Comparative Example 2-1

The copper foil was coated with alloy solder made of Sn (80.0 wt %) and Pb (20.0 wt %), and the rest of the fabrication was the same as that in Example 2-1. The adhesion strength in this instance was 3.9×10⁴ Pa, which is markedly low in comparison with Examples 2-1 through 2-6 above. Also, by observing the cross section taken along the alternate long and short dash line X-X of FIG. 3, it is understood that the coating solder layer (containing lead) was nearly melted, which prevented the electric conducting particles 8a in the resin from entering into the copper foil portion, and no anchor effect by the electric conducting particles 8a could be therefore expected.

### Comparative Example 2-2

The copper foil was coated with alloy solder made of Sn (95 wt %) and Bi (5 wt %), and the rest of the fabrication was the same as that in Example 2-1. The adhesion strength in this instance was 4.4×10⁴ Pa.

In order to check the reliability of the adhesion strength of the copper foil attached to the photo-electric conversion cells in Example 2-1 through Example 2-6 as well as comparative Example 2-1 and Comparative Example 2-2, a change before and after the environmental tests (JISC8917) was analyzed. In short, three environmental tests specified below were conducted. The first environmental test was a temperature cycle test, by which the temperature was controlled over 6 hours from −40° C. to 90° C. in 1 cycle and 200 cycles were repeated. The second environmental test was a humidity cycle test, by which the temperature and relative humidity (RH) were controlled over 6 hours from −40° C. to 85° C. at 85% in 1 cycle and 10 cycles were repeated. The third environmental test was a constant temperature and humidity test, by which the subject was allowed to stand for 1000 hours under the condition that the temperature and the relative humidity (RH) were kept at 85° C. and 85%, respectively. The results of these environmental tests are set forth in Table 1 below.

TABLE 1

| | TEMPER- | | CONSTANT |
|---|---|---|---|
| | ATURE | HUMIDITY | TEMPERATURE |
| | CYCLE | CYCLE | AND HUMIDITY |
| | TEST | TEST | TEST |
| EXAMPLE 2-1 | ◯ | ◯ | ◯ |
| EXAMPLE 2-2 | ◯ | ◯ | ◯ |
| EXAMPLE 2-3 | ◯ | ◯ | ◯ |
| EXAMPLE 2-4 | ◯ | ◯ | ◯ |
| EXAMPLE 2-5 | ◯ | ◯ | ◯ |
| EXAMPLE 2-6 | ◯ | ◯ | ◯ |
| COMPARABLE | X | X | X |
| EXAMPLE 2-1 | | | |
| COMPARABLE | X | X | X |
| EXAMPLE 2-2 | | | |

◯: deterioration in adhesion strength within 10%
X: deterioration in adhesion strength equal to or exceeding 30%

As is obvious from Table 1 above, in Examples 2-1 through 2-6, the adhesion strength varied little, 7 to 8% at most, for all the three environmental tests. On the contrary, in Comparative Examples 2-1 and 2-2, the adhesion strength deteriorated by 30% or more for all the three environmental tests. The reason for this deterioration is thought that the solder, coating the copper foil, started to melt during the attachment due to its low melting point and the surface was roughened, which made the curing of epoxy resin unsatisfactory. It is therefore understood that a non-lead solder material is an optimal material to coat the copper foil.

Also, the solder melted on the surface of the copper foil in Comparative Examples 2-1 and 2-2, whereas the luster of the solder remained intact in Examples 2-1 through 2-6. Hence, when the photo-electric conversion cells are modularized, incident light is expected to reflect on the copper foil surface and goes incident again, thereby contributing to the photo-electric transfer characteristic.

### Example 3

A substrate was formed by forming an aluminum alloy portion on an aluminum alloy substrate or iron-based alloy. On the substrate were provided p-type silicon particles 3 having a particle size of about 0.2 to 0.6 mm. Silicon particles 3 were then bonded to the aluminum alloy by heating in atmosphere for about 10 min. at or above 577° C., which is the eutectic temperature of aluminum and silicon. An insulation material 4 was filled above the silicon particles 3. Subsequently, the top surfaces of the p-type silicon particles 3 were rinsed. A semiconductor layer 5, mixed crystals of n-type crystalline silicon and amorphous silicon, was formed above the silicon particles 3 and the insulation material 4, in a thickness of 300 nm. Further, an ITO film, serving as a transparent electric conducting layer 6, was formed in a thickness of 80 nm.

The electric conducting paste of various kinds set forth in Table 2 below was applied, by means of a dispenser, on the transparent electric conducting layer 6 in the photo-electric conversion cell fabricated in the manner as described above, and a collector electrode was formed through curing by the heat treatment under the heat treatment conditions set forth in Table 2 below. For the samples made as has been described, the adhesion of the electrode (the pull strength by the push-pull gauge), the wettability to the solder, the bonding strength when the take-off electrode was welded to the bus bar portion with the use of solder (the pull strength of the take-off electrode by the push-pull gauge) were measured, the results of which are set forth in Table 2 below.

TABLE 2

| | | | HEAT | | | |
|---|---|---|---|---|---|---|
| | ELECTRIC | | TREATMENT | | | BONDING |
| | CONDUCTING PASTE | | CONDITION | ADHESION OF | | STRENGTH AT |
| | ELECTRIC | | TEMPERATURE | UPPER | | TAKE-OFF |
| | CONDUCTING | | (° C.) × | ELECTRODE | SOLDER | ELECTRODE |
| | POWDER | RESIN | TIME (MIN.) | (N/cm²) | WETTABILITY | (N) |
| EXAMPLE 3-1 | Ag | EPOXY + | 250 × 30 | 99 | ◯ | 3.9 |
| | | PHENOL | | | | |
| EXAMPLE 3-2 | Ag-COATED | EPOXY + | 250 × 30 | 96 | ◯ | 4.0 |
| | Cu | PHENOL | | | | |
| EXAMPLE 3-3 | Cu | EPOXY + | 250 × 30 | 94 | ◯ | 3.8 |
| | | PHENOL | | | | |
| COMPARATIVE | Ag | EPOXY | 130 × 10 | 98 | X | 0 |
| EXAMPLE 3-1 | | | | | | |
| COMPARATIVE | Ag-COATED | EPOXY | 250 × 30 | 96 | X | 0 |
| EXAMPLE 3-2 | Cu | | | | | |
| COMPARATIVE | Ag | PHENOL | 200 × 30 | 0 | ◯ | 0 |
| EXAMPLE 3-3 | | | | | | |

In Comparative Examples 3-1 and 3-2, the adhesion of the transparent electric conducting layer was sufficient; however, the bonding strength of the connection electrodes 12 was not strong enough due to the poor wettability of the solder. The reason for this is thought as follows. That is, sufficient adhesion to the transparent electric conducting layer 6 was achieved because the resin in the electric conducting paste was epoxy resin; however, because the surface of the electric conducting particles in the transparent electric conducting layer remained covered with the resin when the connection electrodes 12 were welded with the use of solder, the resin impaired the wettability of the electric conducting particles in the transparent electric conducting layer to the solder.

In Comparative Example 3-3, the wettability to the solder was satisfactory; however, sufficient adhesion to the transparent electric conducting layer 6 was not achieved. The reason for this is thought that phenol resin underwent degeneration at the temperature at which the welding with the use of solder was performed, and the resin on the surfaces of the electric conducting particles in the transparent electric conducting layer was peeled off, which made it easier for the solder to be wet, whereas phenol resin per se had poor adhesion to the transparent electric conducting layer 6.

On the contrary, in Examples 3-1, 3-2, and 3-3, the adhesion of the transparent electric conducting layer, the wettability to the solder, and the bonding strength to the take-off electrode were all satisfactory. The reason for this is thought that because two kinds of resin were mixed, the epoxy resin increased the adhesion strength between the transparent electric conducting layer and the transparent electric conducting layer 6, while the phenol resin increased the wettability to the solder, which enabled the both properties to be improved at the same time.

### Example 4

On the transparent electric conducting layer 6 in the photo-electric conversion cell fabricated in the manner as described above, electric conducting paste of various kinds as set forth in Table 3 below was applied by means of a dispenser onto the finger portion and the bus bar portion separately, and the transparent electric conducting layer was formed through curing by the heat treatment under the heat treatment conditions set forth in Table 3 below. The bonding strength (the pull strength of the take-off electrode by the push-pull gauge) when the take-off electrode was welded with the use of solder to the bus bar portion in samples made as described above was measured, the results of which are set forth in Table 3 below.

TABLE 3

| | | | | | HEAT | BONDING |
|---|---|---|---|---|---|---|
| | | | | | TREATMENT | STRENGTH |
| | FINGER PORTION | | BUS BAR PORTION | | CONDITION | AT |
| | ELECTRIC | | ELECTRIC | | TEMPERATURE | TAKE-OFF |
| | CONDUCTING | | CONDUCTING | | (° C.) × | ELECTRODE |
| | POWDER | RESIN | POWDER | RESIN | TIME (MIN.) | (N) |
| EXAMPLE 4-1 | Ag | EPOXY + | Ag | EPOXY + | 220 × 30 | 3.8 |
| | | PHENOL | | PHENOL | | |
| EXAMPLE 4-2 | Ag-COATED | EPOXY + | Ag-COATED | EPOXY + | 250 × 30 | 4.1 |
| | Cu | PHENOL | Cu | PHENOL | | |
| EXAMPLE 4-3 | Ag | EPOXY | Ag | EPOXY + | 250 × 30 | 3.9 |
| | | | | PHENOL | | |
| EXAMPLE 4-4 | Ag | EPOXY | Ag-COATED | EPOXY + | 250 × 30 | 4.0 |
| | | | Cu | PHENOL | | |

The bonding strength to the take-off electrode was satisfactory in all Examples 4-1, 4-2, 4-3, and 4-4. It is therefore understood that no trouble will occur when different kinds of electric conducting paste were used for the finger portion and the bus bar portion, respectively. In other words, as in Example 4-2, the finger portion can be made of paste having a good electric conductivity, while the bus bar portion can be made of paste having a good wettability.

### Example 5

In Example 5-1 and Example 5-2, substrates were formed by forming an aluminum alloy portion on an aluminum alloy substrate or SUS 430 through cold rolling via a Ni foil, and by forming Ni alloy on the back surface of an aluminum alloy substrate through cold rolling, respectively. With the use of each substrate, components up to the transparent electric conducting layer 6 were formed, and samples were made by bonding a take-off electrode to the bus bar electrode portion by means of welding with the use of solder on the transparent electric conducting layer 6. Then, the connection electrodes 12 were connected to the back surface of the substrate, which also serves as one electrode in an adjacent photo-electric conversion cell, for each substrate. In this instance, the oxide film was removed with a sand paper from the back surface of the substrate. The connection strength, when connected by means of bonding with the use of solder, ultrasonic welding, and rivets made of Cu or Al, was evaluated using the strength when the take-off electrode was pulled from the back surface of the substrate by the push-pull gauge, the results of which are set forth in Table 4 below.

TABLE 4

| | MATERIAL | | |
|---|---|---|---|
| | OF | | |
| | SUBSTRATE | | CONNECTION |
| | BACK | CONNECTION | STRENGTH |
| | SURFACE | METHOD | (N) |
| EXAMPLE 5-1 | Al ALLOY | ULTRASONIC | 10.2 |
| | | WELDING | |
| EXAMPLE 5-2 | Al ALLOY | RIVET | 8.0 |
| | | (MATERIAL: Cu) | |
| EXAMPLE 5-3 | Al ALLOY | RIVET | 8.2 |
| | | (MATERIAL: Al) | |
| EXAMPLE 5-4 | SUS 430 | ULTRASONIC | 10.0 |
| | | WELDING | |
| EXAMPLE 5-5 | SUS 430 | RIVET | 8.2 |
| | | (MATERIAL: Cu) | |
| EXAMPLE 5-6 | SUS 430 | RIVET | 8.1 |
| | | (MATERIAL: Al) | |
| EXAMPLE 5-7 | SUS 430 | WELDING WITH | 9.8 |
| | | SOLDER | |
| EXAMPLE 5-8 | Ni ALLOY | ULTRASONIC | 9.9 |
| | | WELDING | |
| EXAMPLE 5-9 | Ni ALLOY | RIVET | 8.1 |
| | | (MATERIAL: Cu) | |
| EXAMPLE 5-10 | Ni ALLOY | RIVET | 8.0 |
| | | (MATERIAL: Al) | |
| EXAMPLE 5-11 | Ni ALLOY | WELDING WITH | 9.5 |
| | | SOLDER | |
| COMPARATIVE | Al ALLOY | WELDING WITH | 0 |
| EXAMPLE 5-1 | | SOLDER | |

In Comparative Example 5-1, sufficient connection strength was not achieved by the welding with the use of solder. This is because the back surface of the substrate was made of aluminum alloy, and silicon diffused in the substrate when the silicon particles 3 were bonded, which made the wettability to the solder poor.

On the contrary, for all the samples in Example 5-1 through Example 5-11, sufficient connection strength was attained, and peeling-off was observed in neither the silicon particles 3 nor the insulation layer 4. It is therefore understood that for the substrate formed by providing the aluminum alloy portion through cold rolling on SUS 430 via a Ni foil, and the substrate formed by providing Ni alloy through cold rolling on the back surface of the aluminum alloy substrate, all of the bonding with the use of solder, the ultrasonic welding, the rivets made of Cu or Al can achieve the satisfactory connection. In particular, it is understood that, for the aluminum alloy substrate, although the bonding with the use of solder fails to attain satisfactory connection strength, the bonding by means of the ultrasonic welding and the rivets made of Cu or Al can achieve the satisfactory connection.

### Example 6

Glass electric conducting paste made of aluminum and glass electric conducting paste made of silver were fired at 700 to 800° C. on the back surface of a p-type silicon substrate. The surface of the substrate was then rinsed with an aqueous solution of hydrofluoric acid (HF:pure water=1:100) for cleaning. A semiconductor layer 5, mixed crystals of n-type crystalline silicon and amorphous silicon, was formed above silicon particles 3 and an insulation layer 4, in a thickness of 300 nm. Further, an ITO film, serving as a transparent electric conducting layer 6, was formed in a thickness of 80 nm. The electric conducting paste of various kinds set forth in Table 5 below was applied on the transparent electric conducting layer 6 by means of a dispenser, and a collector electrode was formed through curing by the heat treatment under the heat treatment conditions set forth in Table 5 below. For the samples made as has been described, the adhesion of the electrode (the pull strength by the push-pull gauge), the wettability to the solder, the bonding strength when the take-off electrode was welded to the bus bar portion with the use of solder (the pull strength of the take-off electrode by the push-pull gauge) were measured, the results of which are set forth in Table 5 below.

TABLE 5

| | | | | | HEAT | BONDING |
|---|---|---|---|---|---|---|
| | | | | | TREATMENT | STRENGTH |
| | FINGER PORTION | | BUS BAR PORTION | | CONDITION | AT |
| | ELECTRIC | | ELECTRIC | | TEMPERATURE | TAKE-OFF |
| | CONDUCTING | | CONDUCTING | | (° C.) × | ELECTRODE |
| | POWDER | RESIN | POWDER | RESIN | TIME (MIN.) | (N) |
| EXAMPLE 6-1 | Ag | EPOXY + | Ag | EPOXY + | 220 × 30 | 3.9 |
| | | PHENOL | | PHENOL | | |
| EXAMPLE 6-2 | Ag-COATED | EPOXY + | Ag-COATED | EPOXY + | 250 × 30 | 4.0 |
| | Cu | PHENOL | Cu | PHENOL | | |
| EXAMPLE 6-3 | Ag | EPOXY | Ag | EPOXY + | 250 × 30 | 4.0 |
| | | | | PHENOL | | |
| EXAMPLE 6-4 | Ag | EPOXY | Ag-COATED | EPOXY + | 250 × 30 | 4.1 |
| | | | Cu | PHENOL | | |

The bonding strength to the take-off electrode was satisfactory in Examples 6-1, 6-2, 6-3, and 6-4. It is therefore understood that no trouble will occur when different kinds of electric conducting paste were used for the finger portion and the bus bar portion, respectively. In other words, as in Example 6-4, the finger portion can be made of paste having a good electric conductivity, while the bus bar portion can be made of paste having a good wettability.

In view of the foregoing, according to the photo-electric conversion cell of the invention, it is confirmed that the transparent electric conducting layer can be formed while maintaining sufficient adhesion between the transparent electric conducting layer and the take-off electrode, which in turn makes it possible to connect the photo-electric conversion cells to one another with a sufficient strength.

### Example 7 and Comparative Example 7

A number of p-type silicon particles having a particle size of 0.5 mm were arrayed on an Al substrate by changing a filling ratio, and the silicon particles were bonded to the substrate by heating for 5 min. at 600° C. Polyimide was applied in clearances among the silicon particles in a thickness of about 100 μm, and fired at 200° C. for 30 min. and 350° C. for 60 min. to form an insulation layer.

Subsequently, a film of a mixed layer of n-type amorphous and crystalline materials was deposited in a thickness of about 15 nm above the p-type silicon particles and the insulation layer by means of plasma CVD using a mixed gas made of a silane gas and a slight quantity of a phosphorous compound. Further, a 85-nm-thick ITO film was formed thereon by means of sputtering.

Further, electric conducting paste (for example, DOTITE® FA-705A of Fujikura Kasei), prepared by mixing Ag metal filler and epoxy resin, was applied in clearances among silicon particles and dried at normal temperature, followed by firing at 150° C. for 30 min. to form a photovoltaic generating device. In order to check a quantity of paste present in clearances among the silicon particles in the device, as is shown in FIG. 9, a covering ratio of the collector electrodes (electric conducting paste) with respect to an area, (Sc−Sa), of the substrate except for an area of the semiconductor particles was calculated by reading an image. In short, the covering ratio was found by calculating: covering ratio=Sb/(Sc−Sa)×100. Further, transfer efficiencies of the cell with respect to the filing ratio of the semiconductor particles and the covering ratio of the paste are set forth in Table 6 below.

TABLE 6

| | | PARTICLE | ELEMENT |
|---|---|---|---|
| | COVERING | FILLING | TRANSFER |
| | RATIO | RATIO | EFFICIENCY |
| | (%) | (%) | (%) |
| EXAMPLE 7-1 | 40 | 80 | 8.5 |
| | | 65 | 7.1 |
| | | 50 | 5.3 |
| EXAMPLE 7-2 | 20 | 80 | 8.0 |
| | | 65 | 6.7 |
| | | 50 | 5.0 |
| EXAMPLE 7-3 | 10 | 80 | 7.2 |
| | | 65 | 5.9 |
| | | 50 | 4.5 |
| COMPARATIVE | 5 | 80 | 3.1 |
| EXAMPLE 7-1 | | 65 | 2.5 |
| | | 50 | 1.9 |

As is shown in Table 6 above, when the covering ratio was equal to 10% or higher, the transfer efficiency, representing the device characteristic, had a tendency to decrease in almost proportion to the filling ratio of the silicon particles. On the contrary, when the covering ratio was below 10%, the transfer efficiency deteriorated markedly, and the collector electrodes were no longer able to function properly.

In addition, the transfer efficiency with respect to the covering ratio reached nearly a constant ratio. In the case of the filling at or exceeding this ratio, the covering ratio can be increased as much as possible to the extent that the transfer efficiency is not deteriorated by shadowing the surfaces of the silicon particles.

### Example 8

Paste was prepared by dispersing fine particles, which were resin particles coated with metal, in a solution with an inclusive ratio among semiconductor particles being set to 10% and the covering ratio being maintained to a constant level of 40% in Example 1-1. The solution was applied and dried by evaporation to form the collector electrodes. The transfer efficiency was measured by changing a maintaining time while keeping the heat treatment temperature to 150° C. The relation between the conditions through the observation of the cross section of the collector electrode and the transfer efficiency is set forth in Table 7 below.

TABLE 7

| | PRESENCE RATIO OF METAL PARTICLES (%) | | | |
|---|---|---|---|---|
| | | | OPPOSITE | TRANSFER |
| | ITO | | SIDE | EFFICIENCY |
| | SIDE | MIDDLE | TO ITO | (%) |
| EXAMPLE 8-1 | 70 | 20 | 10 | 9.2 |
| EXAMPLE 8-2 | 50 | 30 | 20 | 8.7 |
| EXAMPLE 8-3 | 30 | 35 | 30 | 7.9 |
| COMPARATIVE | 20 | 30 | 50 | 5.2 |
| EXAMPLE 8-1 | | | | |
| COMPARATIVE | 10 | 20 | 70 | 2.1 |
| EXAMPLE 8-2 | | | | |

As is shown in Table 7, it is more effective when the ratio of the present metal particles had a gradient such that the metal particles were present at a higher ratio at least on the transparent electric conducting layer side.

The present application is in correspondence to Patent Application No. 2003-398792 filed with Japanese Patent Office on Nov. 28, 2003 and Patent Application No. 2004-020583 filed with Japanese Patent Office on Jan. 28, 2004, and the whole disclosure thereof is incorporated herein by reference.

1. A photo-electric conversion cell, comprising:
a substrate, at least one main surface of which is made of a conductor layer;
plural crystalline semiconductor particles provided on the conductor surface of said substrate;
an insulation layer filled in clearances among said crystalline semiconductor particles;
a transparent electric conducting layer provided above said plural crystalline semiconductor particles; and
a collector electrode, formed on said transparent electric conducting layer, to collect electricity from said transparent electric conducting layer,
wherein said substrate is provided with a substrate electrode portion at one end portion, through which the conductor surface of said substrate is exposed.

2. The photo-electric conversion cell according to claim 1, wherein:
said insulation layer is also formed on a side surface of said substrate at an end portion where said substrate electrode portion is not provided.

3. A photo-electric conversion array formed by connecting photo-electric conversion cells in series and/or in parallel,
wherein each photo-electric conversion cell comprises: a substrate, at least one main surface of which is made of a conductor layer; plural crystalline semiconductor particles provided on the conductor surface of said substrate; an insulation layer filled in clearances among said crystalline semiconductor particles; a transparent electric conducting layer provided above said plural crystalline semiconductor particles; and a collector electrode, formed on said transparent electric conducting layer, to collect electricity from said transparent electric conducting layer, and
wherein said substrate is provided with a substrate electrode portion at one end portion, through which the conductor surface of said substrate is exposed; and
wherein a photo-electric conversion cell is connected to another photo-electric conversion cell via a connection electrode that electrically connects said collector electrode in the one photo-electric conversion cell to said substrate electrode portion in the other photo-electric conversion cell.

4. The photo-electric conversion array according to claim 3, wherein:
the electrical connection of said connection electrode and said substrate electrode portion is achieved by means of ultrasonic welding.

5. The photo-electric conversion array according to claim 3, wherein:
said connection electrode is an electrode extended from said collector electrode.

6. The photo-electric conversion array according to claim 5, wherein:
said connection electrode and a portion of said collector electrode connected to said connection electrode, comprise a metal bar coated with a non-lead solder layer on a surface thereof.

7. The photo-electric conversion array according to claim 6, wherein:
said metal bar is chiefly made of one of copper and aluminum, and said non-lead solder layer is chiefly made of tin.

8. The photo-electric conversion array according to claim 5, wherein:
a bent portion is formed somewhere in the middle of said connection electrode.

9. The photo-electric conversion array according to claim 3, wherein:
said collector electrode comprises a finger electrode and a bus bar electrode both formed on said transparent electric conducting layer;
said connection electrode is an electrode extended from said bus bar electrode; and
said finger electrode and said bus bar electrode are electrically connected to each other via an anisotropic electric-conducting adhesion agent disposed in between.

10. The photo-electric conversion array according to claim 3, wherein:
said connection electrode is an electrode bonded onto said collector electrode.

11. The photo-electric conversion array according to claim 10, wherein:
said connection electrode comprises a metal bar coated with a non-lead solder layer on a surface thereof.

12. The photo-electric conversion array according to claim 11, wherein:
said metal bar is chiefly made of one of copper and aluminum, and said non-lead solder layer is chiefly made of tin.

13. The photo-electric conversion array according to claim 10, wherein:
a bent portion is formed somewhere in the middle of said connection electrode.

14. The photo-electric conversion array according to claim 3, wherein:
said collector electrode occupies a region that accounts for 10% to 40%, both inclusive, of an area of air spaces among said semiconductor particles.

15. The photo-electric conversion array according to claim 3, wherein:
said collector electrode is formed by subjecting electric conducting paste, made of heat-cured resin that contains an electric conducting material, to heat treatment.

16. The photo-electric conversion array according to claim 15, wherein:
said collector electrode is provided with a gradient of concentration in such a manner that a concentration of the electric conducting material contained in said collector electrode becomes higher on a side closer to said transparent electric conducting layer.

17. The photo-electric conversion cell according to claim 1, wherein:
said crystalline semiconductor particles are made of silicon.

18. The photo-electric conversion cell according to claim 1, wherein:
said crystalline semiconductor particles have an average particle size of 0.2 to 0.6 mm.

19. The photo-electric conversion cell according to claim 1, wherein:
the conductor layer on said substrate is made of one of aluminum and aluminum alloy.

20. A photo-electric generation system fabricated using the photo-electric conversion array according to claim 3 as an electric power generator, wherein:
the generated electric power is supplied to a load connected thereto.
